(19) United States
(12) Patent Application Publication
(10) Pub. No.: US 2019/0235686 A1
(43) Pub. Date: Aug. 1, 2019

(54) PRESSURE SENSOR AND DISPLAY DEVICE

(71) Applicant: Sharp Kabushiki Kaisha, Sakai City (JP)

(72) Inventors: Takenori MARUYAMA, Sakai City (JP); Jean MUGIRANEZA, Sakai City (JP); Kazutoshi KIDA, Sakai City (JP); Yasuhiro SUGITA, Sakai City (JP); Shinji YAMAGISHI, Sakai City (JP); Yukio MIZUNO, Sakai City (JP); Hiroshi FUKUSHIMA, Sakai City (JP); Hidetsugu KAWAMORI, Sakai City (JP)

(21) Appl. No.: 16/253,271

(22) Filed: Jan. 22, 2019

(30) Foreign Application Priority Data
Jan. 26, 2018 (JP) 2018-011666

(51) Int. Cl. G06F 3/041; H01L 41/047; H01L 41/113; H01L 41/193

(52) U.S. Cl. CPC G06F 3/0414; H01L 41/0472; H01L 41/1871; H01L 41/193; G06F 3/0416; H01L 41/1132

(57) ABSTRACT

A pressure sensor includes a first electrode, a second electrode, a first ferroelectric layer connected to the first electrode and disposed between the first electrode and the second electrode, a second ferroelectric layer connected to the second electrode and disposed between the first ferroelectric layer and the second electrode, and a dielectric layer disposed between the first ferroelectric layer and the second ferroelectric layer.

### CROSS REFERENCE TO RELATED APPLICATION

This application claims priority from Japanese Patent Application No. 2018-011666 filed on Jan. 26, 2018. The entire contents of the priority application are incorporated herein by reference.

### TECHNICAL FIELD

The technology described herein relates to a pressure sensor and a display device.

### BACKGROUND

A known example of a pressure sensor is described in Japanese Unexamined Patent Application Publication No. 2015-155880. The pressure sensor in the publication includes a piezoelectric unit including a piezoelectric sensor, a temperature detection electrode, and a correction computing portion. The piezoelectric sensor includes a piezoelectric sheet that generates piezoelectric signals corresponding to applied loads. The temperature detection electrode is disposed on at least one of surfaces of the piezoelectric sensor. The correction computing portion corrects variations in piezoelectric signal resulting from variations in temperature based on information obtained through the temperature detection electrode and outputs the corrected piezoelectric signals.

### SUMMARY

The pressure sensor described in the above publication does not have the problem of charge generation in the piezoelectric sheet caused by changes in temperature and correctly measures a pressing force. However, the pressure sensor includes special circuit components such as the temperature detection electrode and the correction computing portion for correction of variations in piezoelectric signal, resulting in a higher cost.

The technology described herein was made in view of the above circumstances. An object is to provide a lower-cost pressure sensor that has lower false detection possibility.

A pressure sensor according to the technology described herein includes a first electrode, a second electrode, a first ferroelectric layer connected to the first electrode and disposed between the first electrode and the second electrode, a second ferroelectric layer connected to the second electrode and disposed between the first ferroelectric layer and the second electrode, and a dielectric layer disposed between the first ferroelectric layer and the second ferroelectric layer.

In this configuration, upon application of pressure, the polarized states of the first and second ferroelectric layers are changed by the piezoelectric effect, causing polarization of the dielectric layer located between the first and second ferroelectric layers. At this time, the first and second ferroelectric layers have opposite polarities at the ends adjacent to the dielectric layer and have opposite polarities at the other ends adjacent to the first or second electrode. This causes a potential difference between the first electrode connected to the first ferroelectric layer and the second electrode connected to the second ferroelectric layer, enabling pressure detection using the potential difference. Furthermore, a temperature around the first electrode or the second electrode may change. In such a case, the first and second ferroelectric layers deform and the polarized states of the first and second ferroelectric layers are modified by the pyroelectric effect, causing polarization of the dielectric layer located between the first and second ferroelectric layers. At this time, the first and second ferroelectric layers have the same polarity at the ends adjacent to the dielectric layer and the same polarity at the other ends adjacent to the first or second electrode. In this case, the first and second electrodes have the same polarity, and thus a potential difference is hardly caused therebetween. This reduces false detection caused by a change in temperature. In addition, this configuration does not include special circuit components, which are included in known touch panels, leading to a reduction in cost.

According to the technology described herein, a lower-cost pressure sensor that has lower false detection possibility is provided.

### BRIEF DESCRIPTION OF THE DRAWINGS

FIG. 1 is a cross-sectional view illustrating a liquid crystal display device according to a first embodiment.

FIG. 2 is a plan view illustrating the liquid crystal display device and schematically illustrating a touch panel pattern of a pressure-sensitive touch panel.

FIG. 3 is a cross-sectional view illustrating the pressure-sensitive touch panel.

FIG. 4 is a cross-sectional view illustrating polarized states of ferroelectric layers and a dielectric layer included in the pressure-sensitive touch panel.

FIG. 5 is a cross-sectional view illustrating polarized states of the ferroelectric layers and the dielectric layer with the surface of the pressure-sensitive touch panel being pressed with a finger.

FIG. 6 is a cross-sectional view illustrating polarized states of the ferroelectric layers and the dielectric layer with the temperature of the surface of the pressure-sensitive touch panel being increased by the temperature of the finger.

FIG. 7 is a graph indicating experimental results of a comparative experiment.

### DETAILED DESCRIPTION

### First Embodiment

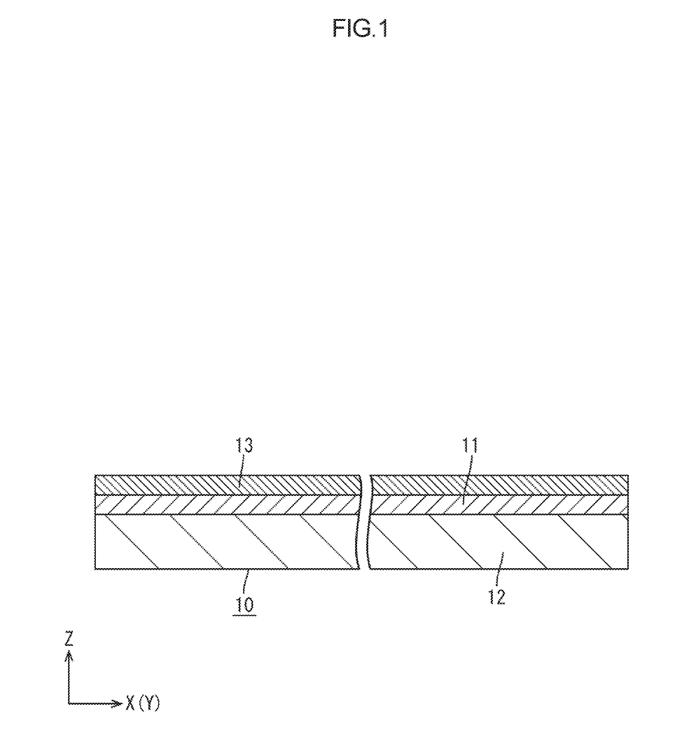

A first embodiment will be described with reference to FIGS. 1 to 7. In this embodiment, a liquid crystal display device (display device) 10 having a pressure detection function and a touch panel function (position detection function) is described as an example. The X axis, the Y axis, and the Z axis are indicated in some of the drawings, and each of the axes indicates the same direction in the respective drawings. The vertical direction is based on FIGS. 1 and 3 to 6, and the upper side in those figures is a front side and the lower side in those figures is a rear side.

As illustrated in FIG. 1, the liquid crystal display device 10 at least includes a liquid crystal panel (display panel) 11 that displays an image, a backlight device (lighting device) 12 that overlaps the rear surface of the liquid crystal panel 11 and applies display light to the liquid crystal panel 11, and a pressure-sensitive touch panel (pressure sensor) 13 that overlaps the front surface of the liquid crystal panel 11. Although not illustrated in detail, the liquid crystal panel 11 includes two glass substrates bonded together with a predetermined gap therebetween and a liquid crystal layer (not illustrated) sealed between the substrates. The liquid crystal layer includes liquid crystal molecules, which are substances whose optical properties are changed by application of an electrical field. The liquid crystal panel 11 has a display area that can display an image at a substantially center of the screen and a frame-shaped non-display area that surrounds the display area at an outer periphery of the screen. Although not illustrated in detail, the backlight device 12 at least includes a light source (such as an LED and an organic EL) and an optical member that allows the light from the light source to pass therethrough and provides optical effects to the light.

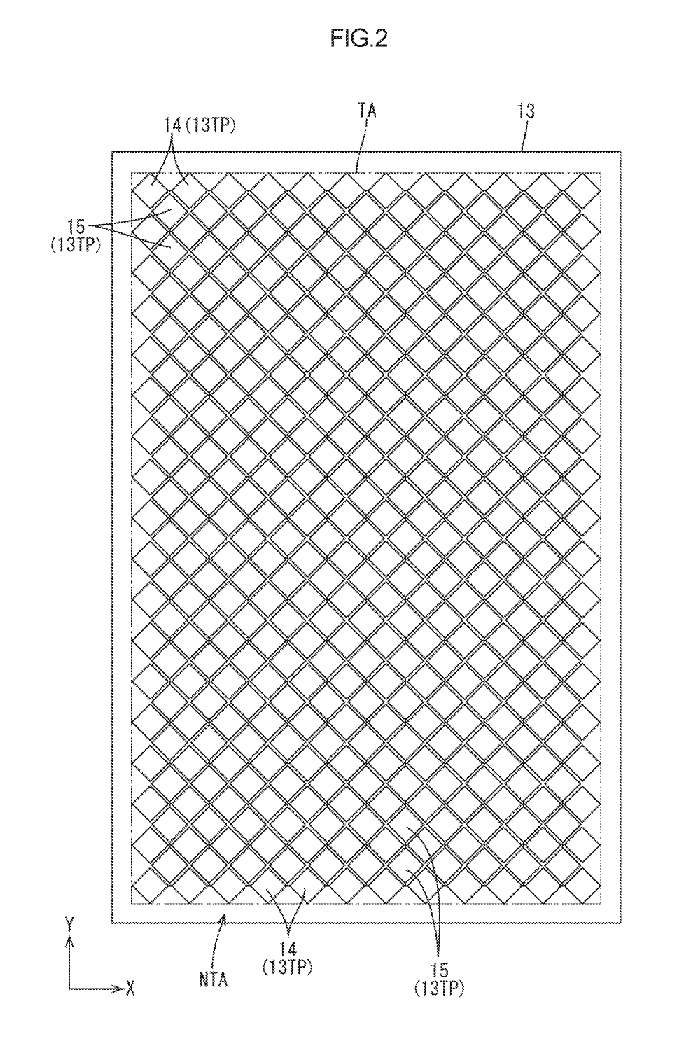

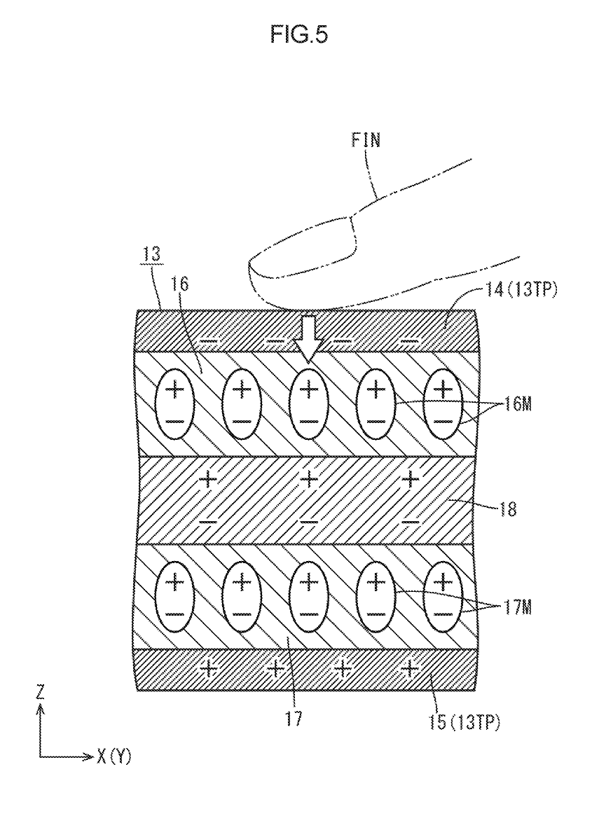

The following is a description of the pressure-sensitive touch panel 13. As illustrated in FIG. 2, the pressure-sensitive touch panel 13 has a touch panel pattern (position detection pattern) 13TP for detection of position touched by the user. The touch panel pattern 13TP is a projected capacitive touch panel pattern and employs self-capacitive detection, for example. The touch panel pattern 13TP at least includes multiple first touch electrodes (first electrodes, first position detection electrodes) 14 and second touch electrodes (second electrodes, second position detection electrodes) 15, which are arranged in a matrix over the display area of the liquid crystal panel 11. The display area substantially corresponds to a touch area TA where the input position is detectable, and the non-display area substantially corresponds to a non-touch area NTA where the input position is undetectable. In FIG. 2, an area surrounded by a one-dot chain line is the touch area TA and the area outside the touch area TA is the non-touch area NTA. When the user touches the screen with a finger FIN (FIG. 5) based on an image in the display area, a capacitance is formed between the finger FIN and the first and second touch electrodes 14 and 15. The capacitance detected at the first and second touch electrodes 14 and 15 near the fin FIN changes as the finger FIN approaches, and the first and second electrodes 14 and 15 become distinguishable from the other first and second electrodes 14 and 15 away from the finger FIN, enabling the detection of the input position. The first and second touch electrodes 14 and 15 are formed of light-transmission and conductive transparent electrode films (ITO or IZO, for example). This allows the display light that has passed through the liquid crystal panel 11 to travel to the front side without being blocked by the first and second touch electrodes 14 and 15.

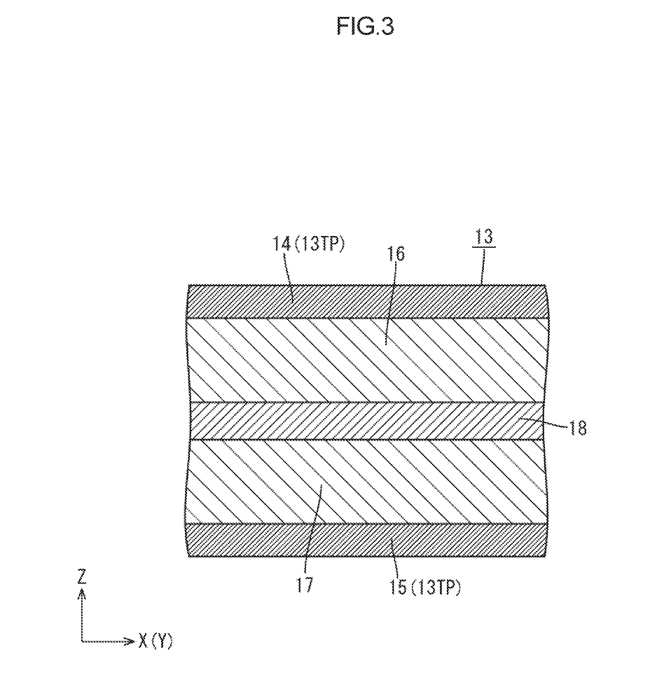

As illustrated in FIG. 3, the pressure-sensitive touch panel 13 includes a first ferroelectric layer 16, a second ferroelectric layer 17, and a dielectric layer 18, in addition to the above-described first and second touch electrodes 14 and 15. The first ferroelectric layer 16, the second ferroelectric layer 17, and the dielectric layer 18 are located between the first touch electrode 14 and the second touch electrode 15, which are located at the front and rear sides of the pressure-sensitive touch panel 13. The dielectric layer 18 is disposed between the first ferroelectric layer 16 and the second ferroelectric layer 17. More specifically described, the first ferroelectric layer 16 is disposed between the first touch electrode 14 and the dielectric layer 18, and the second ferroelectric layer 17 is disposed between the second touch electrode 15 and the dielectric layer 18.

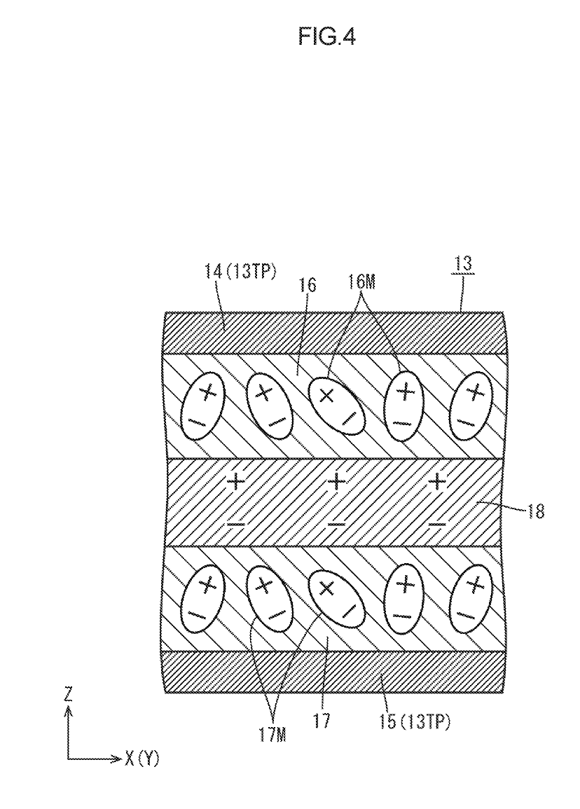

As illustrated in FIG. 3, the first ferroelectric layer 16 has the first touch electrode 14 thereon and is connected to the first touch electrode 14. The second ferroelectric layer 17 has the second touch electrode 15 thereon and is connected to the second touch electrode 15. The first and second ferroelectric layers 16 and 17 are each preferably formed of a polymer, such as poly lactic acid (PLA) and polyvinylidene difluoride (PVDF), and at least have light transmitting properties. More specifically described, a film formed of polyvinylidene difluoride, for example, is uniaxially stretched and is subjected to polarization treatment to form the first and second ferroelectric layers 16 and 17. The first and second ferroelectric layers 16 and 17 formed as above have an optical characteristic that allows the transmitting light to have a phase difference in addition to electrical characteristics of ferroelectric, such as piezoelectricity and pyroelectricity. FIG. schematically illustrates polarized states of the first ferroelectric layer 16, the second ferroelectric layer 17, and the dielectric layer 18 with no pressure application to the pressure-sensitive touch panel 13 and with no temperature change (initial state). In the initial state, as illustrated in FIG. 4, molecules 16M constituting the first ferroelectric layer 16 are generally oriented to be positively polarized at ends adjacent to the first touch electrode 14 (front side) in the thickness direction (Z axis direction) and negatively polarized at the other ends adjacent to the dielectric layer 18 (rear side) in the thickness direction. In the initial state, molecules 17M constituting the second ferroelectric layer 17 are generally oriented to be positively polarized at ends adjacent to the dielectric layer 18 (front side) in the thickness direction and negatively polarized at the other ends adjacent to the second touch electrode 15 (rear side) in the thickness direction. In other words, the polarization directions of the molecules 16M and 17M in the thickness direction are substantially the same in the first and second ferroelectric layers 16 and 17. The polarization direction of the molecules 16M and 17M are reversible, because the first and second ferroelectric layers 16 and 17 are ferroelectric. In FIG. 4, the positive poles and the negative poles of the molecules 16M and 17M are, respectively, indicated by “+” and “−”.

As illustrated in FIG. 4, the dielectric layer 18 between the first ferroelectric layer 16 and the second ferroelectric layer 17 is polarized by an external electrical field. The dielectric layer 18 may be formed of a substantially transparent and high light-transmission adhesive material, such as an optical clear adhesive (OCA) film. The adhesive material may be an ultraviolet curable resin material that is cured when irradiated with ultraviolet rays. The dielectric layer 18 fixes the first ferroelectric layer 16 and the second ferroelectric layer 17. The dielectric layer 18 has a lower hardness and is more deformable than any of the first touch electrode 14, the second touch electrode 15, the first ferroelectric layer 16, and the second ferroelectric layer 17. The dielectric layer 18 in the initial state is positively polarized at an end adjacent to the first ferroelectric layer 16 in the thickness direction (Z direction) and is negatively polarized at an end adjacent to the second ferroelectric layer 17 in the thickness direction. In FIG. 4, the polarity of the dielectric layer 18 is indicated by “+” and “−”.

The pressure-sensitive touch panel 13 having the above-described configuration has the following effects and advantages. As illustrated in FIG. 5, when the surface of the first touch electrode 14, which is the frontmost layer of the pressure-sensitive touch panel 13, is pressed with a finger FIN of the user, the polarized states of the first and second ferroelectric layers 16 and 17 are changed by the piezoelectric effect, changing the polarized state of the dielectric layer 18, which is located between the first and second ferroelectric layers 16 and 17. Specifically described, the molecules 16M constituting the first ferroelectric layer 16 are uniformly oriented to be positively polarized at the ends adjacent to the first touch electrode 14 in the thickness direction and negatively polarized at the other ends adjacent to the dielectric layer 18 in the thickness direction. The molecules 17M constituting the second ferroelectric layer 17 are uniformly oriented to be positively polarized at the ends adjacent to the dielectric layer 18 in the thickness direction and negatively polarized at the other ends adjacent to the second touch electrode 15 in the thickness direction. In other words, the first and second ferroelectric layers 16 and 17 in the initial state are highly polarized and have opposite polarities at the ends adjacent to the dielectric layer 18 and opposite polarities at the ends adjacent to the first or second touch electrode 14 or 15. Thus, the first touch electrode 14 connected to the first ferroelectric layer 16 is negatively charged and the second touch electrode 15 connected to the second ferroelectric layer 17 is positively charged, causing a difference in potential between the first touch electrode 14 and the second touch electrode 15. The difference in potential enables detection of the pressure applied by the finger FIN. Furthermore, the first and second touch electrodes 14 and 15 included in the touch panel pattern 13TP enable detection of the position pressed with the finger FIN.

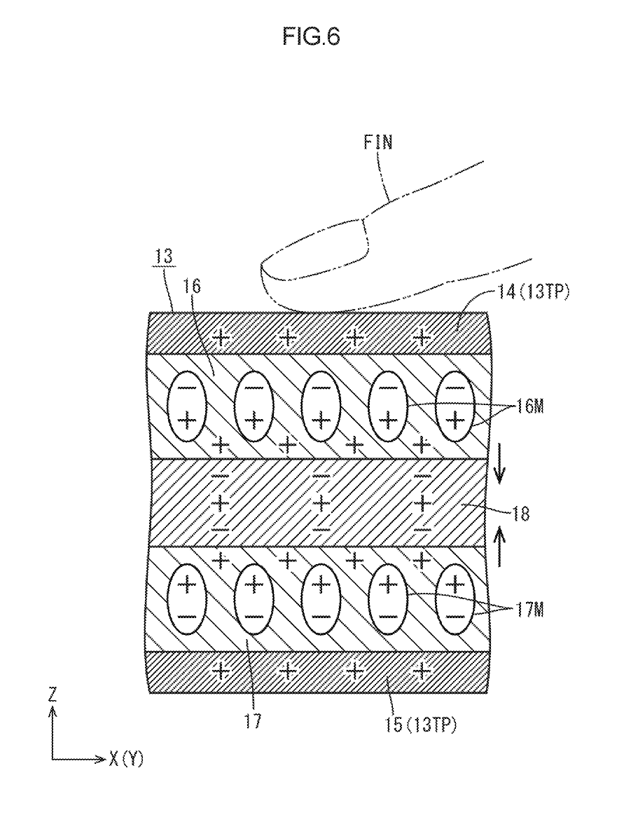

When the finger FIN of the user touches but does not press the surface of the first touch electrode 14, which is the frontmost layer of the pressure-sensitive touch panel 13, the temperature around the first touch electrode 14 increases, as illustrated in FIG. 6. In this case, the first and second ferroelectric layers 16 and 17 are stretched and the polarized states thereof are changed by pyroelectricity, changing the polarized state of the dielectric layer 18 located between the first and second ferroelectric layers 16 and 17. The first and second ferroelectric layers 16 and 17 stretched by the increased temperature are displaced toward the dielectric layer 18 as indicated by arrows in FIG. 6, because the hardness of the dielectric layer 18 is lower than that of the other layers of the pressure-sensitive touch panel 13. Thus, the molecules 16M and 17M in the first and second ferroelectric layers 16 and 17 are uniformly oriented to be positively polarized at the ends adjacent to the dielectric layer 18, which are stretching ends, and negatively polarized at the other ends adjacent to the first or second touch electrode 14 or 15. That is, the polarization direction of the first ferroelectric layer 16 is reversed from that in the initial state illustrated in FIG. 4 and is opposite to the polarization direction of the second ferroelectric layer 17. Thus, the first and second ferroelectric layer 16 and 17 have the same polarity at the ends adjacent to the dielectric layer 18 and have the same polarity at the other ends adjacent to the first or second touch electrode 14 or 15. In such a state, both the first and second touch electrodes 14 and 15 have positive polarity, and thus a potential difference is hardly caused therebetween. This configuration reduces false pressure detection caused by an increase in temperature. False pressure detection caused by a decrease in temperature is also reduced by this configuration. Furthermore, this configuration does not include special circuit components, which are included in known technologies, leading to a reduction in the cost. Furthermore, the first and second touch electrodes 14 and 15 included in the touch panel pattern 13TP enable detection of the position touched with the finger FIN.

In addition, the first and second ferroelectric layers 16 and 17, which are formed of a uniaxially stretched light-transmitting polymer material, each impart a phase difference to the light transmitting therethrough. The phase difference of the transmitting light imparted by the first ferroelectric layer 16 and the phase difference of the transmitting light imparted by the second ferroelectric layer 17 are canceled out each other, improving visibility of the transmitting light. Furthermore, since the first and second ferroelectric layers 16 and 17 and the dielectric layer 18 each have light-transmitting properties as the touch electrodes 14 and 15, the display light passed through the liquid crystal panel 11 is output toward the front side without being blocked.

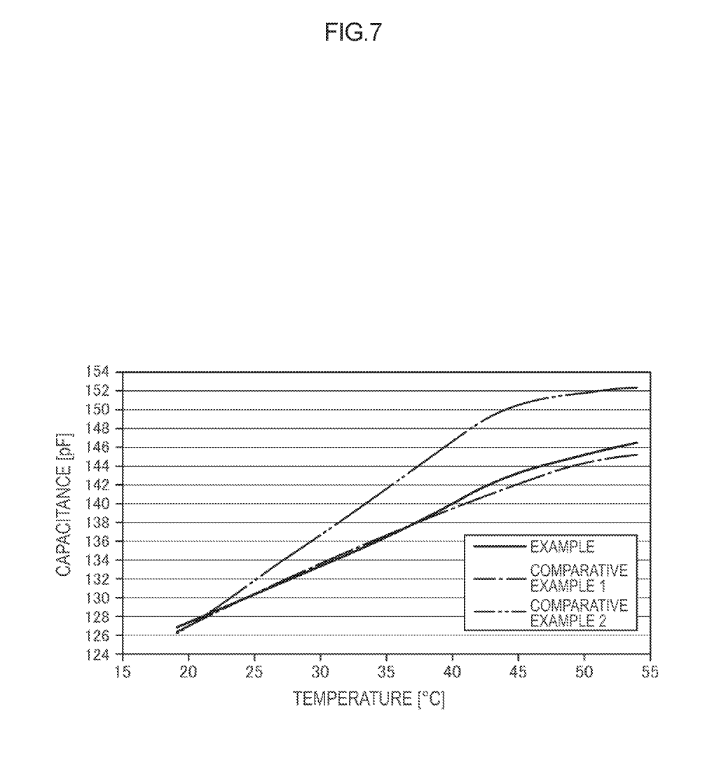

The following comparative experiment was performed. Herein, a comparative example 1 is a non-pressure-detectable touch panel that has the same configuration as the above-described pressure-sensitive touch panel 13 except that the first and second ferroelectric layers 16 and 17 are eliminated, a comparative example 2 is a pressure-sensitive touch panel that has the same configuration as the above-described pressure-sensitive touch panel 13 except that the second ferroelectric layer 17 is eliminated, and an example is a pressure-sensitive touch panel that has the same configuration as the above-described pressure-sensitive touch panel 13. In this comparative experiment, the surfaces of the touch panel of the comparative example 1 and the pressure-sensitive touch panels of the comparative example 2 and the example were pressed with a cylindrical metal member and the temperature of the cylindrical metal member was changed such that the capacitance between the first touch electrode 14 and the second touch electrode 15 was determined at various temperatures. The results are shown in FIG. 7. In FIG. 7, the horizontal axis indicates temperatures of the cylindrical metal member (° C.) and the vertical axis indicates capacitances (pF) between the first touch electrode 14 and the second touch electrode 15. In FIG. 7, a one-dot chain line, a two-dot chain line, and a solid line, respectively, indicate the comparative example 1, the comparative example 2, and the example.

The following is an explanation of the results of the comparative experiment. As can be seen from FIG. 7, the touch panel of the comparative example 1 has the smallest capacitances over almost the full temperature range except for around 20° C. This is probably because that, in the touch panel of the comparative example 1 not including the first and second ferroelectric layers 16 and 17, a potential difference due to a change in temperature is not caused between the first touch electrode 14 and the second touch electrode 15 in principle. In contrast, the pressure-sensitive touch panel of the comparative example 2 has the largest capacitances over almost the full temperature range except for around 20° C. This is probably because that, in the pressure-sensitive touch panel of the comparative example 2, the first ferroelectric layer 16 is uniformly polarized due to a change in temperature and a potential difference is caused between the first touch electrode 14 and the second touch electrode 15. The pressure-sensitive touch panel 13 of the example has lower capacitances than the pressure-sensitive touch panel of the comparative example 2 and has substantially the same capacitance as the touch panel of the comparative example 1 over the full temperature range except for around 20° C. This is probably because that, in the pressure-sensitive touch panel 13 of the example, although the respective first and second dielectric layers 16 and 17 are uniformly polarized due to a change in temperature, the first and second touch electrodes 14 and 15 have the same polarity due to the dielectric layer 18, and a potential difference is hardly caused between the first touch electrode 14 and the second touch electrode 15.

As described above, the pressure-sensitive touch panel (pressure sensor) 13 of the embodiment includes the first touch electrode (first electrode) 14, the second touch electrode (second electrode) 15, the first ferroelectric layer 16 connected to the first touch electrode 14 and disposed between the first touch electrode 14 and the second touch electrode 15, the second ferroelectric layer 17 connected to the second touch electrode 15 and disposed between the first ferroelectric layer 16 and the second touch electrode 15, and the dielectric layer 18 between the first ferroelectric layer 16 and the second ferroelectric layer 17.

In this configuration, upon application of pressure, the polarized states of the first and second ferroelectric layers 16 and 17 are changed by the piezoelectric effect, causing polarization of the dielectric layer 18 located between the first and second ferroelectric layers 16 and 17. At this time, the first and second ferroelectric layers 16 and 17 have opposite polarities at the ends adjacent to the dielectric layer 18 and have opposite polarities at the other ends adjacent to the first or second touch electrode 14 or 15. This causes a potential difference between the first touch electrode 14 connected to the first ferroelectric layer 16 and the second touch electrode 15 connected to the second ferroelectric layer 17, enabling pressure detection using the potential difference. Furthermore, a temperature around the first touch electrode 14 or the second touch electrode 15 may change. In such a case, the first and second ferroelectric layers 16 and 17 deform and the polarized states of the first and second ferroelectric layers 16 and 17 are modified by the pyroelectric effect, causing polarization of the dielectric layer 18 located between the first and second ferroelectric layers 16 and 17. At this time, the first and second ferroelectric layers 16 and 17 have the same polarity at the ends adjacent to the dielectric layer 18 and the same polarity at the other ends adjacent to the first or second touch electrode 14 or 15. In this case, the first and second touch electrodes 14 and 15 have the same polarity, and thus a potential difference is hardly caused therebetween. This reduces false detection caused by a change in temperature. In addition, this configuration does not include special circuit components, which are included in known touch panels, leading to a reduction in cost.

Furthermore, the first ferroelectric layer 16 and the second ferroelectric layer 17 are formed of a uniaxially stretched light-transmitting polymer material. With this configuration, the light passing through the first and second ferroelectric layers 16 and 17 is imparted with a phase difference. The phase difference of the transmitting light imparted by the first ferroelectric layer 16 and the phase difference of the transmitting light imparted by the second ferroelectric layer 17 are cancelled out each other, improving the visibility of the transmitting light.

The dielectric layer 18 has the lower hardness than the first touch electrode 14, the second touch electrode 15, the first ferroelectric layer 16, and the second ferroelectric layer 17. In this configuration, the first and second ferroelectric layers 16 and 17 displace toward the dielectric layer 18 when stretched due to an increase in temperature. Thus, the first and second ferroelectric layers 16 and 17 are positively polarized at the ends adjacent to the dielectric layer 18 and negatively polarized at the ends adjacent to the first or second touch electrode 14 or 15.

The dielectric layer 18 is formed of an adhesive material. In this configuration, the adhesive dielectric layer 18 located between the first ferroelectric layer 16 and the second ferroelectric layer 17 more reliably fix the first and second ferroelectric layers 16 and 17.

The first touch electrode (first position detection electrode) 14 and the second touch electrode (second position detection electrode) 15 forma capacitance with the finger (position input body) FIN that inputs a position, enabling detection of the position inputted by the finger FIN. In this configuration, the position inputted by the finger FIN is able to be detected by using the first and second touch electrodes 14 and 15. This configuration having the position detection function in addition to the pressure detection function reduces the cost, because another touch panel (position sensor) is not required.

The liquid crystal display device (display device) 10 of the embodiment includes the pressure-sensitive touch panel 13 and the liquid crystal panel (display panel) 11, which is disposed over the pressure-sensitive touch panel 13 and configured to display an image. In the liquid crystal display device 10, a proper image corresponding to the detected pressure is displayed on the liquid crystal panel 11, because the pressure-sensitive touch panel 13, which is disposed over the liquid crystal panel 11 configured to display an image, properly detects the pressure with lower false detection, which is probably caused by a change in temperature.

### Other Embodiments

The technology disclosed herein is not limited to the embodiments described above and with reference to the drawings. The following embodiments may be included in the technical scope.

(1) In the above embodiment, the molecules in the first and second ferroelectric layers in the initial state are generally oriented to be positively polarized at the ends adjacent to the front side and negatively polarized at the other ends adjacent to the rear side. However, the molecules in the first and second ferroelectric layers in the initial state may be positively polarized at the ends adjacent to the rear side and negatively polarized at the other ends adjacent to the front side.

(2) In the above embodiment, the directions of polarization of the first and second ferroelectric layers in the initial state are the same. However, the directions of polarization of the first and second ferroelectric layers in the initial state may be opposite.

(3) In the above embodiment, PLA and PVDF are described as examples of the polymer material forming the ferroelectric layers. Examples of the polymer material forming the ferroelectric layers further include a copolymer of PVDF and TrFE or a copolymer of PVDF and ETFE.

(4) In the above embodiment, the ferroelectric layers are formed of a polymer material. However, the ferroelectric layers may be formed of a ceramic material (inorganic material) such as barium titanate (BaTiO₃) and lead zirconate titanate (PZT).

(5) In the above embodiment, the touch electrodes are formed of transparent electrode films. However, the touch electrodes may be formed of metal films. In such a case, the metal film may be a mesh metal film to have light-transmitting properties.

(6) In the above embodiment, the OCA film is described as an example of the dielectric layer. However, the dielectric layer may be formed of another light-transmission adhesive material such as an optical clear resin (OCR). The dielectric layer may be formed of a photo-curable resin that is cured with light other than ultraviolet light, e.g., visible light, or a thermo-setting resin.

(7) In the above embodiment, the touch electrode is disposed on each of the ferroelectric layers. However, light-transmission glass substrates or light-transmission synthetic resin substrates may be further provided, and the touch electrodes and the ferroelectric layers may be attached thereto.

(8) In the above embodiment, the temperature is changed when the surface of the pressure-sensitive touch panel is touched with the finger of the user. However, the temperature around the surface (first touch electrode or second touch electrode) of the pressure-sensitive touch panel may be changed by factors other than the finger. The above-described effects and advantages are also obtained in such a case.

(9) In the above embodiment, the touch electrodes on the ferroelectric layers each have a touch panel function. However, a touch panel including touch electrodes for a touch panel function may be separately provided, and the pressure sensor that includes the ferroelectric layers and the dielectric layer may include first and second electrodes connected to the first and second ferroelectric layers.

(10) In the above embodiment, the pressure-sensitive touch panel is integrally included in the liquid crystal display device. However, the pressure-sensitive touch panel may be independently used. In such a case, light-transmitting properties are not required for the touch electrodes, the ferroelectric layers, and the dielectric layer.

(11) In the above embodiment, the self-capacitive touch panel pattern was described as an example. However, the technology described herein is applicable to a mutual capacitance touch panel pattern. The planar shape of the touch electrodes constituting the touch panel pattern is not limited to a rhombus and may be a rectangle, a circle, or a polygon having five or more sides.

(12) In the above-described embodiments, the pressure-sensitive touch panel and the liquid crystal display device each have a vertically-elongated rectangular shape in a plan view. However, the planar shape of the liquid crystal display device be a horizontally-elongated rectangle, a square, an oval, an ellipse, a circle, a trapezoid, or a shape having a curved portion, for example.

(13) In the above-described embodiments, the liquid crystal display device includes a display panel. However, the technology described herein is applicable to display devices including other types of display panels, such as an organic EL panel, an electrophoretic display panel (EPD), and a micro electro mechanical system (MEMS) display panel.

1. A pressure sensor comprising:
a first electrode;
a second electrode;
a first ferroelectric layer connected to the first electrode and disposed between the first electrode and the second electrode;
a second ferroelectric layer connected to the second electrode and disposed between the first ferroelectric layer and the second electrode; and
a dielectric layer disposed between the first ferroelectric layer and the second ferroelectric layer.

2. The pressure sensor according to claim 1, wherein the first ferroelectric layer and the second ferroelectric layer are each formed of a uniaxially stretched light-transmitting polymer material.

3. The pressure sensor according to claim 1, wherein the dielectric layer has a lower hardness than the first electrode, the second electrode, the first ferroelectric layer, and the second ferroelectric layer.

4. The pressure sensor according to claim 1, wherein the dielectric layer is formed of an adhesive material.

5. The pressure sensor according to claim 1, wherein the first electrode and the second electrode are, respectively, a first position detection electrode and a second position detection electrode that form a capacitance with a position input body that inputs a position, enabling detection of the position inputted by the position input body.

6. A display device comprising:
the pressure sensor according to claim 1; and
a display panel disposed over the pressure sensor and configured to display an image.
